(19) United States
(12) Patent Application Publication
(10) Pub. No.: US 2007/0080725 A1
(43) Pub. Date: Apr. 12, 2007

(54) Power-up signal generator of semiconductor device

(75) Inventors: Sang-Jin Byeon, Kyoungki-do (KR); Seok-Cheol Yoon, Kyoungki-do (KR)

Correspondence Address: MCDERMOTT WILL & EMERY LLP, 600 13TH STREET, N.W., WASHINGTON, DC, 20005-3096, US

(73) Assignee: HYNIX SEMICONDUCTOR INC.

(21) Appl. No.: 11/528,528

(22) Filed: Sep. 28, 2006

(30) Foreign Application Priority Data
Sep. 29, 2005 (KR) 2005-0090965
May 31, 2006 (KR) 2006-0049111

(51) Int. Cl. H03L 7/00

(52) U.S. Cl. 327/143

(57) ABSTRACT

A power-up signal generator of a semiconductor device includes a voltage dividing block, a level detection block, and an output block. The voltage dividing block outputs a divided voltage corresponding to a voltage level of an external power supply voltage. The level detection block is controlled according to the divided voltage, and comprises a pull-up unit and a pull-down unit. The output block outputs a power-up signal having a logic level corresponding to a voltage level of an output node of the level detection block. The pull-up unit and the pull-down unit have different threshold voltage levels with respect to a temperature change.

### FIELD OF THE INVENTION

The present invention relates to a semiconductor technology, and more particularly to a power-up signal generator of a semiconductor device.

### DESCRIPTION OF RELATED ARTS

Generally, P-type channel metal-oxide semiconductor (PMOS) transistors and N-type channel metal-oxide semiconductor (NMOS) transistors used in dynamic random access memories (DRAMs) have certain voltage levels of threshold voltage. Device operation generally becomes stabilized when an external voltage has a voltage level that is twice the threshold voltage (i.e., the addition of a threshold voltage of a PMOS transistor and that of an NMOS transistor) or more. Also, when the voltage level of the external voltage is greater than a necessary voltage level, an internal power supply voltage is generated. Therefore, in typical DRAMs, a power-up signal generator generates a power-up signal that indicates when the external voltage increases to a necessary voltage level.

After the external power supply voltage is supplied, the power-up signal generator outputs a power-up signal having a logic low until reaching a predetermined voltage level. As the external power supply voltage exceeds the predetermined voltage level, being in a stabilized state, the logic state of the power-up signal transits to a logic high. An internal circuit of a semiconductor memory device operates in response to the power-up signal. If the internal circuit operates as the logic state of the power-up signal transits to the logic high before the external power supply voltage reaches the predetermined voltage level, malfunction of the internal circuit may result.

As the current semiconductor technology is focused on the micronization and high-integration, the power-up signal generally varies depending on the process, temperature and voltage. Thus, maintaining an enabled state of the power-up signal after the predetermined voltage level is reached is generally important for device reliability and stability.

FIG. 1 illustrates a circuit diagram of a conventional power-up signal generator.

The conventional power-up signal generator includes a voltage dividing block 100, a level control block 110, a level detection block 120, and a power-up signal output block 130. The voltage dividing block 100 includes resistors R11 and R12 connected in series between a terminal of an external power supply voltage VEXT and a terminal of a ground voltage VSS and generates a divided voltage corresponding to a voltage level of the external power supply voltage VEXT at a node A1.

The level control block 110 includes an NMOS transistor N11 connected between the node A1 and the terminal of the external power supply voltage VEXT and receiving the ground voltage VSS as a substrate bias voltage. Two terminals of the NMOS transistor N11 are connected with the node A1. The level control block 110 blocks a gate of an NMOS transistor N12 of the level detection block 120 from being supplied with a voltage of which level is greater than the predetermined voltage level.

The level detection block 120 includes the NMOS transistor N12 that performs a pull-down operation and a PMOS transistor P11 that performs a pull-up operation. The NMOS transistor N12 of the level detection block 120 is connected between a node A2 and the terminal of the ground voltage VSS and receives the ground voltage VSS as a substrate bias voltage. A gate of the NMOS transistor N12 of the level detection block 120 receives the divided voltage through the node A1. The PMOS transistor P11 of the level detection block 120 is connected between the node A2 and the terminal of the external power supply voltage VEXT and receives the external power supply voltage VEXT as a substrate bias voltage. A gate of the PMOS transistor P11 of the level detection block 120 receives the ground voltage VSS.

The power-up signal output block 130 includes an inverter INV11 that receives a voltage generated at the node A2 and outputs a power-up signal PWRUP thereafter. The power-up signal PWRUP is in a logic low state due to the PMOS transistor P11 of the level detection block 120. As the voltage level of the external power supply voltage VEXT increases, the voltage level of the node A1 also increases. When the voltage level of the node A1 increases to a predetermined level, the NMOS transistor N12 of the level detection block 120 turns on. As a result, the logic state of the power-up signal PWRUP transits to a logic high state.

Instead of a single polysilicon-based gate structure obtained when gates of NMOS and PMOS transistors are formed through a single gate process, the gates of the PMOS and NMOS transistors P11 and N12 of the level detection block 120 are formed in a dual polysilicon-based structure to achieve low power consumption and high-integration.

In general, a dual polysilicon-based structure is obtained when gates of NMOS and PMOS transistors through two steps of gate processes. PMOS and NMOS transistors having the dual polysilicon-based structure have nearly the same change in the threshold voltage level.

The PMOS and NMOS transistors P11 and N12 having the dual polysilicon-based structure usually have the same temperature characteristics. In other words, threshold voltage variations of the PMOS and NMOS transistors P11 and N12 due to the temperature change become the same. As the temperature increases, the threshold voltage levels of the PMOS and NMOS transistors P11 and N12 are likely to decrease and the turn-on time of the NMOS transistor N12 often becomes shorter. As a result, the power-up signal PWRUP may vary to a great extent depending on the temperature change.

### SUMMARY OF THE INVENTION

It is, therefore, an object of the present invention to provide a power-up signal generator that can generate a power-up signal at a desired moment by decreasing the variation of a power-up signal dependent on a temperature change.

In accordance with an aspect of the present invention, there is provided a power-up signal generator of a semiconductor device, the power-up signal generator including: a voltage dividing block outputting a divided voltage corresponding to a voltage level of an external power supply voltage; a level detection block controlled according to the divided voltage and comprising a pull-up unit and a pull-down unit, wherein the pull-up and pull-down units include transistors; and an output block outputting a power-up signal having a logic level corresponding to a voltage level of an output node of the level detection block, wherein the pull-up unit and the pull-down unit have different threshold voltage levels with respect to a temperature change.

In accordance with another aspect of the present invention, there is provided a power-up signal generator, including: a voltage dividing block outputting a divided voltage corresponding to a change in a voltage level of an external power supply voltage; a level detection block comprising a pull-up unit that has a constant load value and a pull-down unit that has a variable load value according to the divided voltage; and an output block outputting a power-up signal having a logic level corresponding to a voltage level of an output node of the level detection block, wherein the pull-up unit comprises at least one PMOS transistor that receives the external power supply voltage as a substrate bias voltage, and the pull-down unit includes one NMOS transistor that receives a ground voltage as the substrate bias voltage and another NMOS transistor that receives a self-bias voltage as the substrate bias voltage.

In accordance with still another aspect of the present invention, there is provided a power-up signal generator, including: a voltage dividing block outputting a divided voltage corresponding to a change in a voltage level of an external power supply voltage; a level detection block comprising a pull-up unit and a pull-down unit, each having a variable load value according to the divided voltage; and an output block outputting a power-up signal having a logic level corresponding to a voltage level of an output node of the level detection block, wherein the pull-up unit comprises at least one PMOS transistor that receives the external power supply voltage as a substrate bias voltage, and the pull-down unit includes one NMOS transistor that receives a ground voltage as the substrate bias voltage and another NMOS transistor that receives a self-bias voltage as the substrate bias voltage.

In accordance with a further another aspect of the present invention, there is provided a power-up signal generator, including: a voltage dividing block outputting a divided voltage corresponding to a change in a voltage level of an external power supply voltage; a level detection block comprising a pull-up unit that has a variable load value according to the divided voltage and a pull-down unit that has a constant load value; and an output block outputting a power-up signal having a logic level corresponding to a voltage level of an output node of the level detection block, wherein the pull-up unit comprises at least one PMOS transistor that receives the external power supply voltage as a substrate bias voltage, and the pull-down unit includes one NMOS transistor that receives a ground voltage as the substrate bias voltage and another NMOS transistor that receives a self-bias voltage as the substrate bias voltage.

In accordance with a even further another aspect of the present invention, there is provided a power-up signal generator, including: a voltage dividing block dividing an external power supply voltage level into a predetermined voltage level; a level detection block inputting the divided voltage and comprising at least one pull-up transistor and at least one pull-down transistor, both formed through a dual polysilicon-based gate process; and an output block outputting a power-up signal having a logic level corresponding to a voltage level of an output node of the level detection block, wherein the level detection block further comprises another pull-down transistor configured in a self-bulk bias type and coupled between the pull-down transistor and a terminal of a ground voltage, thereby achieving differently implemented pull-up and pull-down characteristics depending on a temperature change.

### BRIEF DESCRIPTION OF THE DRAWINGS

The above and other objects and features of the present invention will become better understood with respect to the following description of the specific embodiments given in conjunction with the accompanying drawings, in which:

FIG. 1 illustrates a circuit diagram of a conventional power-up signal generator;

FIGS. 2A to 2D illustrate various circuit diagrams of a power-up signal generator in accordance with a first embodiment of the present invention;

FIGS. 3A to 3D illustrate various circuit diagrams of a power-up signal generator in accordance with a second embodiment of the present invention; and

FIGS. 4A to 4D illustrate various circuit diagrams of a power-up signal generator in accordance with a third embodiment of the present invention.

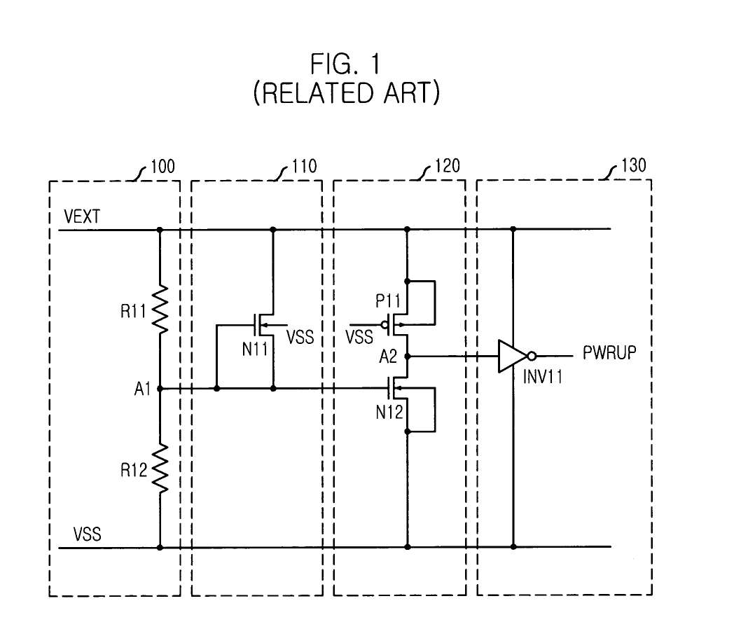

### DETAILED DESCRIPTION OF THE INVENTION

A power-up signal generator of a semiconductor device in accordance with various embodiments of the present invention will be described in detail with reference to the accompanying drawings.

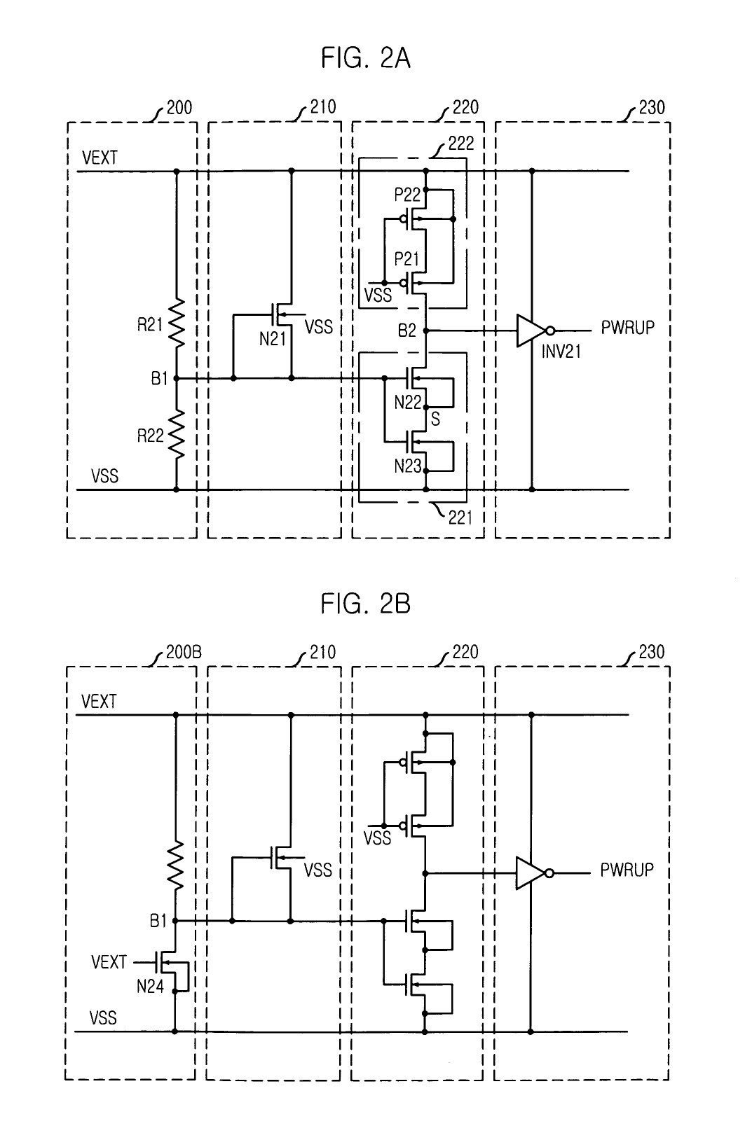

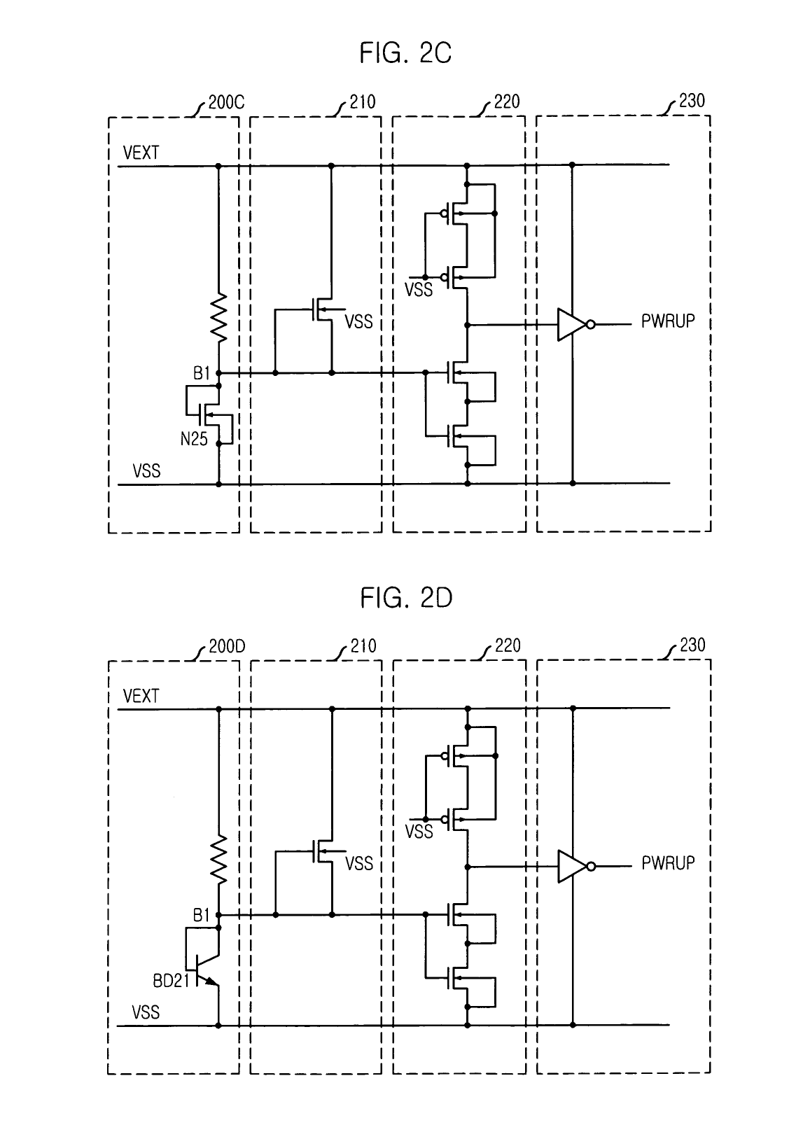

FIG. 2A illustrates a circuit diagram of a power-up signal generator in accordance with a first embodiment of the present invention.

The power-up signal generator includes a voltage dividing block 200, a level control block 210, a level detection block 220, and a power-up signal output block 230. The voltage dividing block 200 generates a divided voltage corresponding to a change in a voltage level of an external power supply voltage VEXT. The voltage dividing block 200 includes a resistor R21 coupled between a terminal of an external power supply voltage VEXT and a node B1 and a resistor R22 coupled between the node B1 and a terminal of a ground voltage VSS.

The level control block 210 impedes the level detection block 220 from receiving a voltage whose level is greater than a predetermined voltage level. The voltage is generated at the node B1. The level control block 210 includes a first NMOS transistor N21 coupled between the terminal of the external power supply voltage VEXT and the node B1 and receiving the ground voltage VSS as a substrate bias voltage. Two terminals of the first NMOS transistor N21 are commonly coupled to the node B1.

The level detection block 220 includes a pull-down unit 221 that performs a pull-down operation and a pull-up unit 222 that performs a pull-up operation. The pull-down unit 221 includes second and third NMOS transistors N22 and N23 and has a load value that is variable depending on the voltage level of the node B1. The pull-up unit 222 includes first and second PMOS transistors P21 and P22 and has a load value that is constant. The ground voltage VSS is supplied to a gate of each of the first and second PMOS transistors P21 and P22.

In more detail of the level detection unit 220, the second NMOS transistor N22 receives the divided voltage generated at the node B1 of the voltage dividing block 200 through a gate of the second NMOS transistor N22. The second NMOS transistor N22 also receives a self-bias voltage S as the substrate bias voltage. The third NMOS transistor N23 receives the divided voltage through a gate thereof and receives the ground voltage VSS as the substrate bias voltage. The ground voltage VSS is supplied to the gate of each of the first and second PMOS transistors P21 and P22. The external power supply voltage VEXT is supplied to the first and second PMOS transistors P21 and P22 as the substrate bias voltage. Operation characteristics of the aforementioned NMOS and PMOS transistors will be described later. Although the pull-down unit 221 and the pull-up unit 222 in the present embodiment are configured to have two of the NMOS and PMOS transistors, the pull-down unit 221 and the pull-up unit 222 can be configured to have more than two of the NMOS and PMOS transistors.

The power-up signal output block 230 includes an inverter INV21 that outputs a power-up signal having a logic level corresponding to a voltage level of a node B2. Operation characteristics of the power-up signal generator will be described herein below.

The power-up signal PWRUP is in a logic low state by the first and second PMOS transistors P21 and P22 of the level detection unit 220. As the voltage level of the external power supply voltage VEXT increases, the voltage level of the node B1 also increases. When the voltage level of the node B1 increases to a certain level, the second and third NMOS transistors N22 and N23 of the level detection unit 220 turn on, causing the power-up signal PWRUP to have a logic high value.

In the conventional power-up signal generator, the pull-up transistor and the pull-down transistor have the same degree of change in the threshold voltage level with respect to the temperature change. The power-up signal PWRUP is generated too early due to the decrease in the threshold voltage levels of the PMOS and NMOS transistors as the temperature increases. However, according to the present embodiment, the power-up signal generator generates the power-up signal PWRUP at a desired moment by the second and third NMOS transistors N22 and N23 of the pull-down unit 221 because the second NMOS transistor N22 receives the self-bias voltage S.

For instance, assuming that the second NMOS transistor N22 and the first PMOS transistor P21 have a threshold voltage of approximately 0.7 V, as the temperature increases, both the pull-up and pull-down transistors of the conventional power-up signal generator usually have a threshold voltage changing by approximately 0.5 V. Thus, the logic state of the power-up signal PWRUP transits to a logic high state more rapidly than a desired moment. In contrast, according to the present embodiment, as the temperature increases, the first PMOS transistor P21 of the power-up signal generator has a threshold voltage of approximately 0.5 V, while the second NMOS transistor N22 has a threshold voltage of approximately 0.6 V. Hence, the logic state of the power-up signal PWRUP transits to a logic high state more slowly than the aforementioned rapid moment. As a result, the power-up signal PWRUP varies less.

FIGS. 2B to 2D illustrate other various circuit diagrams of the power-up signal generator in accordance with the first embodiment of the present invention. Like reference numerals denote like elements described in FIG. 2A. Particularly, the level control unit 210, the level detection unit 220, and the power-up signal output unit 230 are substantially the same as those described in FIG. 2A. Instead of the resistor R22, the voltage dividing units 200B, 200C and 200D have an NMOS transistor N24 (see FIG. 2B), a diode-coupled NMOS transistor N25 (see FIG. 2C) and a diode-coupled bipolar junction transistor BD21 (see FIG. 2D), respectively. Although not illustrated, a diode-coupled PMOS transistor may be used instead of the diode-coupled NMOS transistor N25 (see FIG. 2C).

The above configuration allows reduction in the voltage level of the node B1 with use of the threshold voltage of the transistor that decreases as the temperature increases. Therefore, the power-up signal PWRUP of which logic state transits rapidly as the temperature increase varies less.

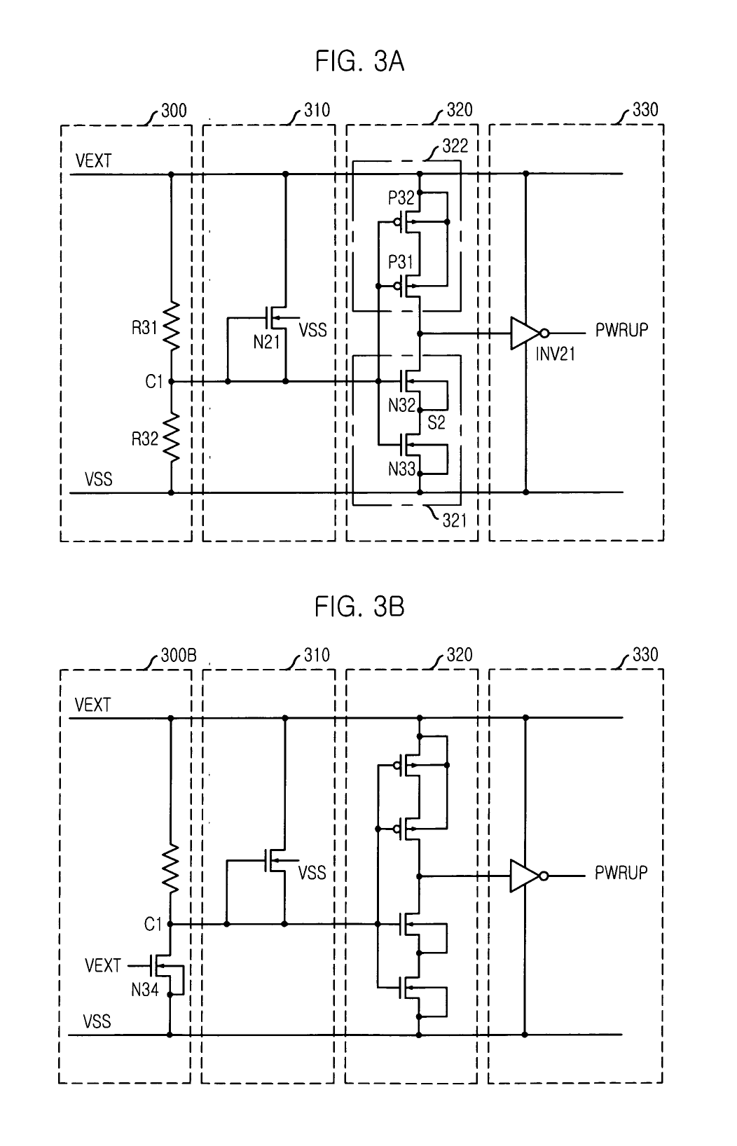

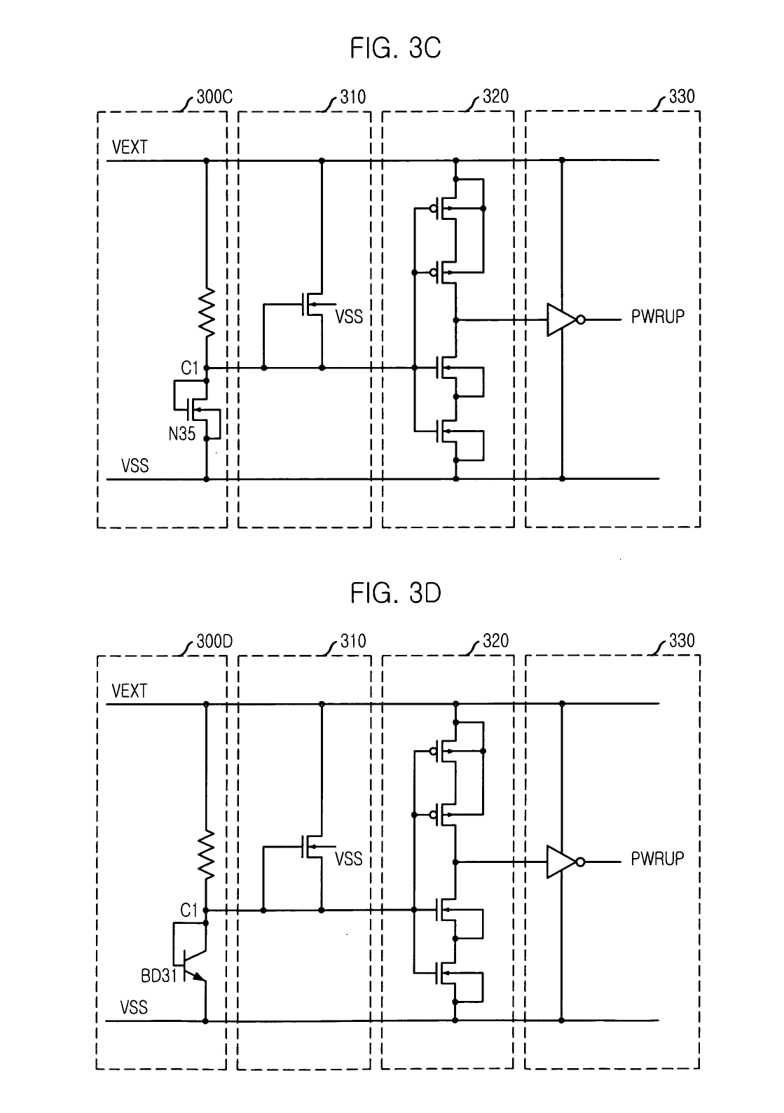

FIGS. 3A to 3D illustrate various circuit diagrams of a power-up signal generator in accordance with a second embodiment of the present invention. The power-up signal generator includes a voltage dividing block 300, a level control block 310, a level detection block 320, and a power-up signal output unit 330. The configuration of the voltage dividing block 300, the level control block 310, and the power-up signal output block 330 are substantially the same as that of the voltage dividing block 200, the level control block 210 and the power-up signal output block 230 illustrated in FIG. 2A. The level detection block 320 has a different configuration from the level detection block 220 illustrated in FIG. 2A.

The level detection block 320 illustrated in FIG. 3A includes a pull-down unit 321 and a pull-up unit 322. The pull-down unit 321 and the pull-up unit 322 have load values changing according to a divided voltage generated at a node C1. The pull-down unit 321 includes NMOS transistors N32 and N33 each of which gate receives the divided voltage. The pull-up unit 322 includes PMOS transistors P31 and P32 each of which gate receives the divided voltage.

In more detail of the level detection unit 320, the NMOS transistor N32 receives the divided voltage generated at the node C1 through the gate of the NMOS transistor N32. The NMOS transistor N32 also receives a self-bias voltage S2 as the substrate bias voltage. The other NMOS transistor N33 receives the divided voltage through the gate thereof and receives a ground voltage VSS as the substrate bias voltage. The divided voltage is supplied to the gate of each of the PMOS transistors P31 and P32, and the external power supply voltage VEXT is supplied to the PMOS transistors P31 and P32 as the substrate bias voltage. Although the pull-down unit 321 and the pull-up unit 322 in the present embodiment are configured to have two of the NMOS and PMOS transistors, the pull-down unit 321 and the pull-up unit 322 may be configured to have more than two of the NMOS and PMOS transistors.

FIGS. 3B to 3D illustrate other various circuit diagrams of the power-up signal generator in accordance with the second embodiment of the present invention. Like reference numerals denote like elements described in FIG. 3A. Particularly, the level control unit 310, the level detection unit 320, and the power-up signal output unit 330 are substantially the same as those described in FIG. 3A. Instead of the resistor R32, the voltage dividing units 300B, 300C and 300D has an NMOS transistor N34 (see FIG. 3B), a diode-coupled NMOS transistor N35 (see FIG. 3C) or a diode-coupled bipolar junction transistor BD31 (see FIG. 3D), respectively. Although not illustrated, a diode-coupled PMOS transistor may be used instead of the diode-coupled NMOS transistor N35 (see FIG. 3C)

The above configuration allows the less variation in the logic state of the power-up signal PWRUP even though the temperature increases.

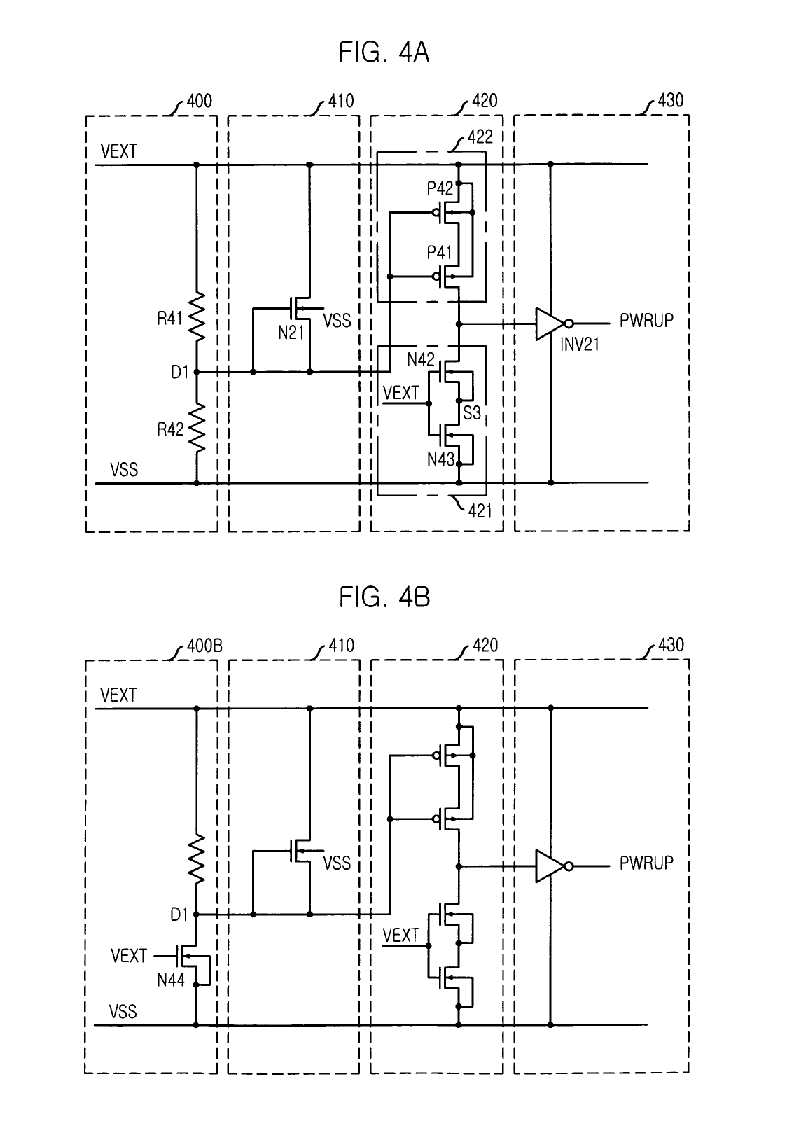

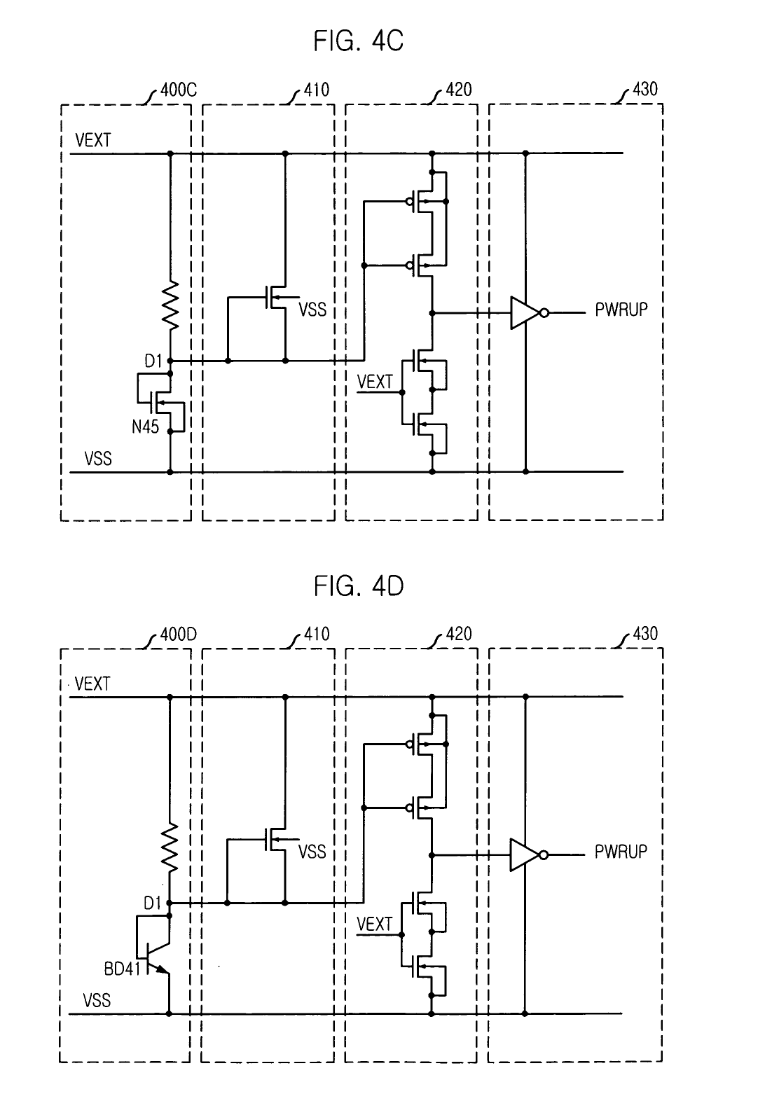

FIGS. 4A to 4D are various circuit diagrams of a power-up signal generator in accordance with a third embodiment of the present invention. The power-up signal generator includes a voltage dividing block 400, a level control block 410, a level detection block 420, and a power-up signal output unit 430. The configuration of the voltage dividing block 400, the level control block 410, and the power-up signal output block 430 are substantially the same as that of the voltage dividing block 200, the level control block 210 and the power-up signal output block 230 illustrated in FIG. 2A. The level detection block 420 has a different configuration from the level detection block 220 illustrated in FIG. 2A.

The level detection block 420 includes a pull-down unit 421 and a pull-up unit 422. The pull-up unit 422 has a load value that is variable according to a divided voltage generated at a node D1. The pull-down unit 421 has a load value that is constant when the pull-down unit 421 receives an external power supply voltage VEXT. The pull-down unit 421 includes NMOS transistors N42 and N43 each of which gate receives the external power supply voltage VEXT. The pull-up unit 422 includes PMOS transistors P41 and P42 each of which gate receives the divided voltage generated at the node D1, so that the load value of the pull-up unit 422 is variable.

In more detail of the configuration of the level detection block 420, the NMOS transistor N42 receives the external power supply voltage VEXT through the gate thereof and also a self-bias voltage S3 as a substrate bias voltage. The other NMOS transistor N43 receives the external power supply voltage VEXT through the gate thereof and also a ground voltage VSS as the substrate bias voltage. The gate of each of the PMOS transistors P41 and P42 receive the voltage generated at the node D1 and also the external power supply voltage VEXT as the substrate bias voltage. As similar to the first embodiment, the pull-down unit 421 and the pull-up unit 422 according to the third embodiment may be configured in multiple numbers.

FIGS. 4B to 4D illustrate other various circuit diagrams of the power-up signal generator in accordance with the third embodiment of the present invention. Like reference numerals denote like elements described in FIG. 4A. Particularly, the level control unit 410, the level detection unit 420, and the power-up signal output unit 430 are substantially the same as those described in FIG. 4A. Instead of the resistor R42, the voltage dividing units 400B, 400C and 400D have an NMOS transistor N44 (see FIG. 4B), a diode-coupled NMOS transistor N45 (see FIG. 4C) or a diode-coupled bipolar junction transistor BD41 (see FIG. 4D), respectively. Although not illustrated, a diode-coupled PMOS transistor may be used instead of the diode-coupled NMOS transistor N45 (see FIG. 4C)

The above configuration allows the less variation in the logic state of the power-up signal PWRUP even though the temperature increases.

According to various embodiments of the present invention, the MOS transistors configured in the pull-up unit are supplied with the external power supply voltage VEXT as the substrate bias voltage. Among the MOS transistors configured in the pull-down unit, at least one MOS transistor, e.g., the second NMOS transistor N22 in FIG. 2A, is supplied with the self-bias voltage as the substrate bias voltage, and at least another MOS transistor, e.g., the third NMOS transistor N23 in FIG. 2A, is supplied with the ground voltage VSS as the substrate bias voltage. Therefore, even though the PMOS transistors and the NMOS transistors, formed through a dual polysilicon-based gate process, have substantially the same variation degree of a threshold voltage due to the temperature; the NMOS transistors of the pull-down unit are supplied with the substrate bias voltage having different voltage levels. Because of the supply of the different voltage levels of the substrate bias voltage to the transistors of the pull-down unit, the transistors of the pull-up unit and the transistors of the pull-down unit generally have different variation degrees of the threshold voltage caused by the temperature.

The threshold voltage variation causes the NMOS transistors of the pull-down unit to turn on more slowly than the conventional NMOS transistors of the pull-down unit. Thus, the logic state of the power-up signal PWRUP does not transit rapidly, thereby reducing the variation in the power-up signal. As a result, the power-up signal can be generated at a desired moment, and this reliable power-up signal can contribute to a stable circuit operation.

The present application contains subject matter related to the Korean patent application Nos. KR 2005-0090965 and 2006-0049111, filed in the Korean Patent Office respectively on Sep. 29, 2005, and May 31, 2006, the entire contents of which being incorporated herein by reference.

While the present invention has been described with respect to certain preferred embodiments, it will be apparent to those skilled in the art that various changes and modifications may be made without departing from the spirit and scope of the invention as defined in the following claims.

What is claimed is:

1. A power-up signal generator of a semiconductor device, the power-up signal generator comprising:
a voltage dividing block outputting a divided voltage corresponding to a voltage level of an external power supply voltage;
a level detection block controlled according to the divided voltage and comprising a pull-up unit and a pull-down unit, wherein the pull-up and pull-down units include transistors; and
an output block outputting a power-up signal having a logic level corresponding to a voltage level of an output node of the level detection block, wherein the pull-up unit and the pull-down unit have a different threshold voltage level with respect to a temperature change.

2. The power-up signal generator of claim 2, further comprising a level control block blocking the divided voltage whose voltage level is greater than a predetermined voltage level from being inputted to the level detection block.

3. The power-up signal generator of claim 1, wherein the transistors included in the pull-up and pull-down units are formed using a dual polysilicon-based gate process.

4. A power-up signal generator comprising:
a voltage dividing block outputting a divided voltage corresponding to a change in a voltage level of an external power supply voltage;
a level detection block comprising a pull-up unit that has a constant load value and a pull-down unit that has a variable load value according to the divided voltage; and
an output block outputting a power-up signal having a logic level corresponding to a voltage level of an output node of the level detection block,
wherein the pull-up unit comprises at least one PMOS transistor that receives the external power supply voltage as a substrate bias voltage, and the pull-down unit includes one NMOS transistor that receives a ground voltage as the substrate bias voltage and another NMOS transistor that receives a self-bias voltage as the substrate bias voltage.

5. The power-up signal generator of claim 4, further comprising a level control block blocking the divided voltage whose voltage level is greater than a predetermined voltage level from being inputted to the level detection block.

6. The power-up signal generator of claim 5, wherein the voltage dividing block comprises:
a resistor of which one end is coupled to a terminal of the external power supply voltage; and
a load unit coupled between the resistor and a terminal of the ground voltage.

7. The power-up signal generator of claim 6, wherein the load unit includes a resistor.

8. The power-up signal generator of claim 6, wherein the load unit includes an MOS transistor receiving the external power supply voltage through a gate of the MOS transistor.

9. The power-up signal generator of claim 6, wherein the load unit includes an MOS transistor coupled to form a diode structure.

10. The power-up signal generator of claim 6, wherein the load unit includes a bipolar junction transistor coupled to form a diode structure.

11. The power-up signal generator of claim 5, wherein the output block includes an inverter that receives a voltage of the output node.

12. The power-up signal generator of claim 5, wherein the level control block includes an NMOS transistor of which one terminal and gate are commonly coupled to a node that outputs the divided voltage and another terminal is coupled to the terminal of the external power supply voltage.

13. A power-up signal generator comprising:
a voltage dividing block outputting a divided voltage corresponding to a change in a voltage level of an external power supply voltage;
a level detection block comprising a pull-up unit and a pull-down unit, each having a variable load value according to the divided voltage; and
an output block outputting a power-up signal having a logic level corresponding to a voltage level of an output node of the level detection block,
wherein the pull-up unit comprises at least one PMOS transistor that receives the external power supply voltage as a substrate bias voltage, and the pull-down unit includes one NMOS transistor that receives a ground voltage as the substrate bias voltage and another NMOS transistor that receives a self-bias voltage as the substrate bias voltage.

14. The power-up signal generator of claim 13, further comprising a level control block blocking the divided voltage whose voltage level is greater than a predetermined voltage level from being inputted to the level detection block.

15. The power-up signal generator of claim 14, wherein the voltage dividing block comprises:
a resistor of which one end is coupled to a terminal of the external power supply voltage; and
a load unit coupled between the resistor and a terminal of the ground voltage.

16. The power-up signal generator of claim 15, wherein the load unit includes a resistor.

17. The power-up signal generator of claim 15, wherein the load unit includes an MOS transistor receiving the external power supply voltage through a gate of the MOS transistor.

18. The power-up signal generator of claim 15, wherein the load unit includes an MOS transistor coupled to form a diode structure.

19. The power-up signal generator of claim 15, wherein the load unit includes a bipolar junction transistor coupled to form a diode structure.

20. The power-up signal generator of claim 14, wherein the output block includes an inverter that receives a voltage of the output node.

21. The power-up signal generator of claim 14, wherein the level control block includes an NMOS transistor of which one terminal and gate are commonly coupled to a node that outputs the divided voltage and another terminal is coupled to the terminal of the external power supply voltage.

22. A power-up signal generator comprising:
a voltage dividing block outputting a divided voltage corresponding to a change in a voltage level of an external power supply voltage;
a level detection block comprising a pull-up unit that has a variable load value according to the divided voltage and a pull-down unit that has a constant load value; and
an output block outputting a power-up signal having a logic level corresponding to a voltage level of an output node of the level detection block,
wherein the pull-up unit comprises at least one PMOS transistor that receives the external power supply voltage as a substrate bias voltage, and the pull-down unit includes one NMOS transistor that receives a ground voltage as the substrate bias voltage and another NMOS transistor that receives a self-bias voltage as the substrate bias voltage.

23. The power-up signal generator of claim 22, further comprising a level control block blocking the divided voltage whose voltage level is greater than a predetermined voltage level from being inputted to the level detection block.

24. The power-up signal generator of claim 23, wherein the voltage dividing block comprises:
a resistor of which one end is coupled to the terminal of the external power supply voltage; and
a load unit coupled between the resistor and a terminal of the ground voltage.

25. The power-up signal generator of claim 24, wherein the load unit includes a resistor.

26. The power-up signal generator of claim 24, wherein the load unit includes an MOS transistor receiving the external power supply voltage through a gate of the MOS transistor.

27. The power-up signal generator of claim 24, wherein the load unit includes an MOS transistor coupled to form a diode structure.

28. The power-up signal generator of claim 24, wherein the load unit includes a bipolar junction transistor coupled to form a diode structure.

29. The power-up signal generator of claim 23, wherein the output block includes an inverter that receives a voltage of the output node.

30. The power-up signal generator of claim 23, wherein the level control block includes an NMOS transistor of which one terminal and gate are commonly coupled to a node that outputs the divided voltage and another terminal is coupled to the terminal of the external power supply voltage.

31. A power-up signal generator comprising:
a voltage dividing block dividing an external power supply voltage level into a predetermined voltage level;
a level detection block inputting the divided voltage and comprising at least one pull-up transistor and at least one pull-down transistor, both formed through a dual polysilicon-based gate process; and
an output block outputting a power-up signal having a logic level corresponding to a voltage level of an output node of the level detection block,
wherein the level detection block further comprises another pull-down transistor configured in a self-bulk bias type and coupled between the pull-down transistor and a terminal of a ground voltage, thereby achieving differently implemented pull-up and pull-down characteristics depending on a temperature change.

32. The power-up signal generator of claim 31, further comprising a level control block blocking the divided voltage whose voltage level is greater than a predetermined voltage level from being inputted to the level detection block.
